(19) United States
(12) Patent Application Publication
(10) Pub. No.: US 2007/0120115 A1
(43) Pub. Date: May 31, 2007

(54) ORGANIC LIGHT-EMITTING ELEMENT, METHOD OF MANUFACTURING ORGANIC LIGHT-EMITTING ELEMENT, LIGHT-EMITTING DEVICE, AND ELECTRONIC APPARATUS

(75) Inventors: Rie MAKIURA, Suwa-shi, Nagano-ken (JP); Tomoyuki OKUYAMA, Suwa-shi, Nagano-ken (JP); Takeo KAWASE, Suwa-shi, Nagano-ken (JP)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 11/470,472

(22) Filed: Sep. 6, 2006

(30) Foreign Application Priority Data
Oct. 21, 2005 (JP) 2005-307854

(51) Int. Cl. H01L 29/08

(52) U.S. Cl. 257/40

(57) ABSTRACT

An organic light-emitting element comprises: an anode;an organic light-emitting layer formed on one surface of the anode, an electron transportation layer formed on the organic light-emitting layer; and a cathode formed on a side being opposite to the organic light-emitting layer with respect to the electron transportation layer. A main material of the electron transportation layer is composed of an organic compound with electron transportation characteristic having at least one element that holds a unshared electron pair, and a metal ion including at least one kind of an alkali metal ion, alkaline earth metal ion and rare earth metal ion.

### BACKGROUND

1. Technical Field

The present invention relates to an organic light-emitting element, a method of manufacturing an organic light-emitting element, a light-emitting device, and an electronic apparatus.

2. Background

An electroluminescent (EL) element is provided with a light-emitting organic layer (organic electroluminsecent layer) installed between an anode and a cathode. It is possible to greatly reduce an applied voltage with this element comparing to an inorganic EL element and manufacture the element that emits various colored light beams.

Currently, researches, which proposing device structures provided with various layers between an anode and a light-emitting organic layer (a light-emitting layer) or an organic light-emitting layer and a cathode, are being actively carried out in order to achieve an organic light-emitting element showing higher performances.

One of such layers is an electron transport layer installed between an anode and a light-emitting layer and/or an electron injection layer installed between an electron transport layer and a cathode. The performances of these electron transport layer and electron injection layer should be urgently improved since they greatly affect the device characteristics.

For example. JPA2005-63910 discloses a structure having the improvement of the characteristic of an electron injection layer. Namely, a metal compound is mixed in an electron injection layer by co-evaporating an organic compound having the electron transportation characteristic and a metal compound including an alkali metal that shows a low working function.

Such electron injection layer, however, is to tenaciously lower driving voltage and improve emitting efficiency and not to improve durability.

Further, an electron injection layer is formed by a vacuum evaporation method, needing large facilities and being inferior in productivity since it is difficult to accurately adjust evaporation speed when two or more materials are simultaneously deposited.

### SUMMARY

The advantage of the present invention is to provide an organic light-emitting element showing superiority in emitting efficiency and durability, a method of manufacturing such element with high productivity, a reliable emitting device provided with such organic light-emitting element and an electronic apparatus.

A main aspect of the present invention is described below.

An organic light-emitting element of the invention includes:, an anode; an organic light-emitting layer formed on one surface of the anode, an electron transportation layer formed on the organic light-emitting layer; a cathode formed on a side being opposite to the organic light-emitting layer with respect to the electron transportation layer. The main material of the electron transportation layer is composed of an organic compound with electron transportation characteristic having at least one element that holds a unshared electron pair, and a metal ion including at least one kind of an alkali metal ion, alkaline earth metal ion and rare earth metal ion.

The organic light-emitting element including the above composition shows superiority in emitting efficiency and durability.

It is preferable in the organic light-emitting element of the invention that an element holding an unshared electron pair be at least one kind of N, O, P, S, As and Se.

This composition stabilizes the structure of an organic compound.

It is preferable in the organic light-emitting element of the invention that the organic compound be a condensed heterocycle compound including an element with the unshared electron pair or its derivative.

This composition further stabilizes the structure of an organic compound.

It is preferable in the organic light-emitting element of the invention that an element with the unshared electron pair included in the organic compound be linked with other element such as double or triple links and polarized to the other linked element.

This composition further surely stabilizes the structure of an organic compound.

It is preferable in the organic light-emitting element of the invention that the volume ratio of the metal ion to the organic compound during transposing electrons be expressed as the following: B/A is equal to or more than 0.2, where A is numbers of elements that are obtained by subtracting the linked numbers of the elements such as double links or triple links from the total numbers of elements having the unshared electron pair in the organic compound. B is numbers of the metal ions.

This structure improves electron transportation capability and durability of the element.

According to another aspect of the invention, a method of manufacturing an organic light-emitting element comprises: compounding a liquid material including the organic compound and the metal ion by dissolving the organic compound and a metal compound including one kind of an alkali metal, alkaline earth metal and rare earth metal into a solvent and dissociating the metal ion from the metal compound; forming the electron transportation layer by supplying the liquid material onto the organic light-emitting layer and drying the liquid material; and forming the cathode on the side opposite to the organic light-emitting layer with respect to the electron transportation layer.

The method can manufacture an organic light-emitting element having superiority in emitting efficiency and durability with high productivity.

It is preferable in the method of manufacturing an organic light-emitting element of the invention that the compounding a liquid material mix a first solution in which the organic compound is dissolved with a second solution in which the metal compound is dissolved so that the volume ratio of the metal ion to the organic compound during transposing electrons be expressed as the following: B/A is equal to or more than 0.2, where A is numbers of elements that are obtained by subtracting the linked numbers of the elements such as double links or triple links from the total numbers of elements having the unshared electron pair in the organic compound. B is numbers of the metal ions.

The method can manufacture an organic light-emitting element having superiority in emitting efficiency and durability with further high productivity.

It is preferable in the method of manufacturing an organic light-emitting element of the invention that the solvent does not easily swell the organic light-emitting layer or dissolve the organic light-emitting layer.

This method can prevent an emitting material from changing in its property and deteriorating, an thickness of the emitting layer from being extremely thin, avoiding lowering light-emitting efficiency as a result.

It is preferable in the method of manufacturing an organic light-emitting element of the invention that the solvent be a polar protic solvent.

The polar protic solvent is preferable since it does not easily swell many organic light-emitting layers and dissolve them, but easily dissolves a metal compound and dissociates a metal ion.

It is preferable in the method of manufacturing an organic light-emitting element of the invention that a major component of a polar protic solvent be at least one kind of water and alcohol.

This component can surely dissociate a metal ion from a metal compound and easily prepare a material for forming an electron transportation layer.

It is preferable in the method of manufacturing an organic light-emitting element of the invention that the alcohol be a unit alcohol in which the numbers of carbons are one to seven. Such unit alcohol highly dissolves a metal compound.

It is preferable in the method of manufacturing an organic light-emitting element of the invention that the metal compound be at least one kind of a metal salt and a metal complex.

These metal compounds are preferable since they are relatively stable in the atmosphere, easily handled and easily dissolves a metal ion.

A emitting device of the present invention is provided with the organic light-emitting element of the invention.

This device can show a highly reliable emitting device.

An electronic apparatus of the invention is provided with the emitting device of the present invention.

This apparatus can show a highly reliable emitting apparatus.

### BRIEF DESCRIPTION OF THE DRAWINGS

The invention will be described with reference to the accompanying drawings, wherein like numbers reference like elements.

FIG. 1 is a schematic diagram showing a cross section according to an embodiment of a light-emitting element of the invention.

FIG. 2 shows cross section of an embodiment of a display in which the light-emitting element of the invention is applied.

FIG. 3 is a perspective view of mobile type (or note type) personal computer in which an electronic apparatus of the invention is applied.

FIG. 4 is a perspective view of a mobile phone (including PHS) in which an electronic apparatus of the invention is applied.

FIG. 5 is a perspective view of a digital still camera in which an electronic apparatus of the invention is applied.

### DESCRIPTION OF EXEMPLARY EMBODIMENTS

Embodiments of the invention with respect to an organic light-emitting element, a method of manufacturing an organic light-emitting element, a light-emitting device, and an electronic apparatus of the invention will be described accompanying drawings.

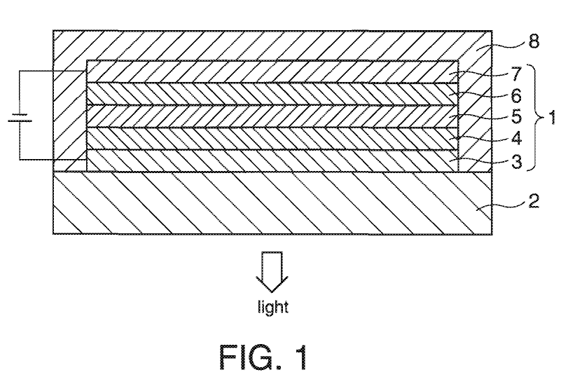

FIG. 1 is a schematic diagram showing a cross section according to an embodiment of a light-emitting element of the invention. Here, an upper portion of the figure is defined as “upper” and a lower portion of the figure is defined as “lower” hereafter.

An organic light-emitting element (an organic electroluminescent element) 1 comprises an anode 3 formed on a substrate 2, an anode 3, a hole transportation layer 4, a light-emitting layer 5, an electron transportation layer 6 and a cathode 7. These multi layers are deposited in order from the anode 3 between the anode 3 and the cathode 7. All components are encapsulated by a sealing member 8.

The substrate 2 supports the organic light-emitting element 1(called as the light-emitting element1hereafter.) The light-emitting element 1 has a structure called as a bottom emission type in which light emits from the substrate 2. Hence, the substrate 2 and the anode 3 are transparent (non color, colored transparent or colored semitransparent.)

As a material for the substrate, a resin such as polyethylene terephthalate, polyethylene naphthalate, polypropylene, cycloolefin polymer, polvamide, polyethersulfone, polymethylmethacrylate,polycarbonate,and polyalylate, a glass such as quartz glass and soda glass are cited one kid or two kinds of them are combined for use.

The average thickness of the substrate 2 is not limited. But, it is preferably from 0.1 to 30 mm, and more preferably from 0.1 to 10 mm.

Here, in case of a top emission type in which light emits from the side opposite to the light-emitting element 1 and the substrate 2, either a transparent substrate or a opaque substrate can be used as the substrate 2.

As an opaque substrate, a substrate made of ceramic such as alumina, metal substrate such as stainless steel on which the surface is coated with an oxide layer (an insulating layer), and a resin substrate are cited.

The anode 3 is an electrode by which holes are injected into the hole transportation layer 4 described hereafter. As a material for the anode 3, a material having large work function and superior conductivity is preferable.

As a material for the anode 3, indium tin oxide (ITO), Indium zinc oxide (IZO), In₃O₃, SnO₂, SnO₂ including Sn, an oxide material such as ZnO including Al, and Au, Pt, Ag, and Cu or alloys including them are cited. One or two kinds of them are combined for use.

The average thickness of the anode 3 is not limited. But, it is preferably from 10 to 200 nm, and more preferably from 50 to 150 nm.

The cathode 7 is an electrode by which electrons are injected into the electron transportation layer 6 described hereafter. As a material for the cathode 7, a material having small work function is preferable.

As a material for the cathode 7, Li, Mg, Ca, Sr, La, Ce, Er, Eu, Sc, Y, Yb, Ag, Cu, Al Cs Rb and an alloy including them are cited. One or two kinds of them are combined for use, and plural layers of them are deposited for example.

In particular, when an alloy is used for a material of the cathode 7, an alloy including a stable metal such as Ag, Al, and Cu is preferable. More specifically ,an alloy such as MgAg, AlLi, CuLi is preferable. The electron injection efficiency of the cathode 7 and the stability of it can be improved by using these alloys as a material for the cathode 7.

The average thickness of the cathode 7 is not limited. But, it is preferably from 100 to 10000 nm, and more preferably from 200 to 500 nm.

In case of a top emission type, a material having small function or an alloy including them is deposited with keeping transparency and its thickness 5 to 20 nm. Further, transparent high conductive material such as ITO is deposited on the surface of the material with its thickness 100 to 500 nm

Here, the light-emitting element 1 of the embodiment is a bottom emission type that does not need the transparency of the cathode 7.

The hole transportation layer 4 is formed on the anode 3. The hole transportation layer 4 transports holes injected by the anode to the light-emitting layer 5.

As a material for the hole transportation layer 4, polyarylamine.florene-arylamine copolymer, florene-bithiophene copolymer, poly(N-vinylcarbazole), polyvinylpyrene, polyvinylanthracene, polythiophene, polyalkilthiopehne, polyhexylthiopehne, poly(p-phenylenevinylene), ployethynylenevinylene, pyreneformaldehyde resin, ethylcarbazole formaldehyde resin, and these derivatives are cited. One or more than two kinds of them are combined for use.

Further, these compounds may be mixed with other compounds. As an example, poly(3,4-ethylenedioxythiopehne/styrene sulphone acid)(PEDOT/PSS) is cited as a mixture including polythiophene.

The average thickness of the hole transportation layer 4 is not limited. But, it is preferably from 10 to 150 nm, and more preferably from 50 to 100 nm.

The light-emitting layer (an organic light-emitting layer) 5 is formed on the hole transportation layer 4. Electrons from the electron transportation layer 6 described later and holes from the hole transportation layer 4 are supplied (injected) to the light-emitting layer 5. Then, electrons are recombined with holes within the light-emitting layer 5 and excitons are generated by energy discharged at the recombination, discharging (emitting) energy (fluorescent light or phosphorescence when the excitons return the ground state.

As a material for the light-emitting layer 5, a benzene compound such as 1,3,5-tris[(3-phenyl-6-tri-fluoromethyl) quinoxaline-2-yl ]benzol (TPQ1), and 1,3,5-tris[[3-(4-t-butyl phenyl-6-trisfluoromethyl) quinoxaline-2-yl ]benzol (TPQ2), a metal or non metal phthalocyanine compound such as phthalocyanine, cupper phthalocyanine (CuPc), iron phthalocyanine, low molecule compounds such as tris(8-hydroxyquinolinolate)aluminum Alqa₃)factoris(2-phenylpyridine)Iridium(Ir(ppy)₃), high molecule compounds such as oxadiazole high molecule, triazole high molecule, carbazole high molecule, polyflorene high molecule, and polyparaphenylenevinylene high molecule are cited. One or two kinds of them are combined for use.

The average thickness of the light-emitting layer 5 is not limited. But, it is preferably from 10 to 150 nm, and more preferably from 50 to 100 nm. The electron transportation layer 6 is formed on the light-emitting layer 5. The electron transportation layer 6 transports electrons injected by the cathode 7 to the light-emitting layer 5.

The present invention features the structure of this electron transportation layer 6 (composition of materials in particular.) The detail of this feature is described later.

The average thickness of the electron transportation layer 6 is not limited. But, it is preferably from 1 to 100 nm, and more preferably from 10 to 50 nm.

The sealing member 8 covers over the light-emitting element 1 (the anode 3, the hole transportation layer 4, the light-emitting layer 5, the electron transportation layer 6 and the cathode 7) and seals them with air tight, avoiding the infiltration of oxygen and water. Installing the sealing member 8 improves the reliability of the light-emitting element 1 and prevent it from deteriorating and changing its property, further improving durability as result.

As a material for the sealing member 8, Al, Au, Cr, Nb, Ta, Ti, an alloy including them, oxide silicon and various resin are cited. In case of using a conductive material for the sealing member 8, installing an insulating film between the sealing member 8 and the light-emitting element 1 is preferable to avoid short circuit, if it is necessary.

Further, the sealing member 8 may be formed as the following. Two plain plates may be located opposite to the substrate 2 and the space between them may be sealed with a sealing material such as a thermal cured resin.

The inventor devoted himself to improve the characteristic of electron transportation in the electron transportation layer having an organic compound with electron transportation property as a main material and the characteristics and the durability of the organic light-emitting element.

As a result, the inventor found that the electron transportation property of the electron transportation layer and the characteristics and durability of an organic light-emitting element are fairly improved by adding alkali metal, alkali earth metal or rare earth metal as metal ions into the electron transportation layer. The electron transportation layer has an organic compound with electron transportation property as a main material that includes elements holding a unshared electron pair.

It is assumed that these As the result of luminance of it and lowering the driving voltage of it. Further, reducing the HOMO level can constrain transporting non-combined holes into the cathode, effectively accumulate holes at the interface between the light-emitting layer and the electron transportation layer. Accordingly, it become possible for these holes to contribute to recombination again, improving the light emission efficiency.

Further, it is assumed that the improvement of the durability is due to the following reasons. First, diffusing metal ions into the light-emitting layer and optical quenching caused by metal ions can be constrained since the organic compound chemically reacts with metal ions. Second, the three dimensional structure of the element is not easily deformed when transporting electrons because of stabilizing the structure of the organic compound due to the chemical interaction, improving the stability of the layer in driving.

The present invention can be attained based on the above backgrounds. Namely, a main material of the electron transportation layer 6 is composed of an organic compound with electron transportation characteristic having at least one element that holds a unshared electron pair, and a metal ion including at least one kind of an alkali metal ion, alkaline earth metal ion and rare earth metal ion

Here, as elements holding a unshared electron pair, elements belonging to the five B group, such as N, P, As, Sb and Bi, elements belonging to the six B group such as O. S, Se, Te, and Po, elements belonging to the seven B group such as F, Cl, br, I, At are cited. At least one kind of N, O, P, S, As and Se is preferable. These elements have high electronegativity, deviating electrons a little bit toward these element's side in the structure of the organic compound. Accordingly, these elements can enhance an organic compound to further interact with metal ions, stabilizing the structure of the organic compound and constraining the diffusion or metal ions. Further, the bond order of these elements is moderately high so that these elements have an unshared electron pair interacting with metal ions and easily link with other elements. Accordingly, it is possible for them to enter into various organic compounds.

It is preferable that an organic compound hold aromatic series (I) including elements with the unshared electron pair or thing (II) in which elements with the unshared electron pair is linked with other element such as double or triple links and polarized to the other linked elements. Accordingly, these structures make electron density easily deviated toward elements with the unshared electron pair, certainly stabilizing the structure of an organic compound.

As an concrete example of the above (I), the compound shown in the following formula 1, or the combination of arbitrary two kinds of them are cited. In the formula 1, Q is independent and indicates N, O, P, S, As and Se.

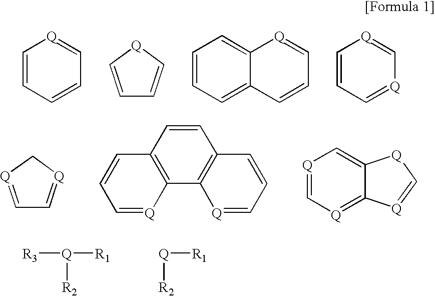

As an concrete example of the above (II), the compound shown in the following formula 2, or the combination of arbitrary two kinds of them are cited, for example. As a combination of Q₁ with Q₂, a double combination such as C═O, N═O, P═O, Se═O, C═S, and P═S, or a triple combination such as C≡N are cited, for example. Here, the bond order of Q₁ is larger than that Of Q₂. Namely, Q₁ is bonded with groups such as a phenyl and alkyl or elements except Q₂.

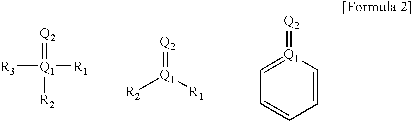

Otherwise, an organic compound may have both the above (I) and (II).

As organic compounds showing the above features and excellent electron transportation property, the compound indicated as the following formulas 3 to 10 or their derivatives are cited for example. The electron transportation compound layer 6 of which a main material includes the above organic compound and the metal ions shows excellent electron transportation efficiency and durability.

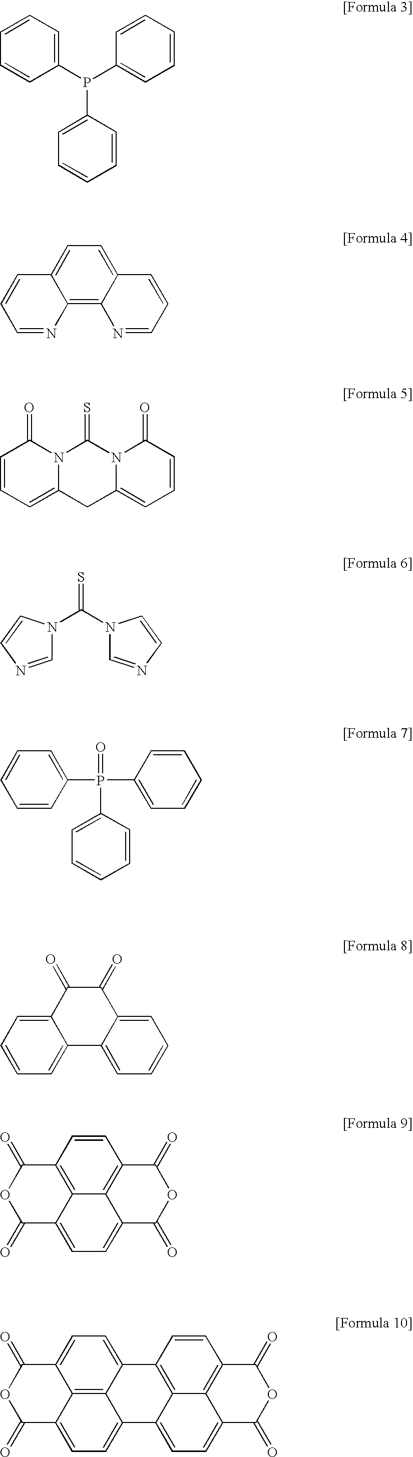

On the other hand, as a metal ion, one is arbitrarily selected from alkali metal ions, alkali earth metal ions, rare earth metal ions, depending on a kind of organic compounds, and not specifically limited. But, metal ions such as Li, Cs, Ca, Mg and Yb are preferable when using condensed heterocycle compounds expressed as the formula 4 or their derivatives as organic compounds.

It is preferable in the electron transportation layer 6 that the volume ratio of the metal ion to the organic compound be expressed as the following: B/A be equal to or more than 0.2, where A is numbers of elements that are obtained by subtracting the linked numbers of the elements such as double links or triple links from the total numbers of elements having the unshared electron pair in the organic compound. B is numbers of the metal ions. It is further preferable that the ratio be 0.2 to 0.5. The ratio of B/A in the above range can make numbers of metal ions be in just proportion to an organic compound, certainly stabilizing the structure of an organic compound. Further, the injection efficiency of electrons from the cathode 7 to the electron transportation layer 6 is sufficiently improved due to the work of metal ions. This ratio further improves the characteristics of the electron transportation layer 6.

Further, the above numerical range of the ratio B/A can sufficiently reduce numbers of metal ions that do not chemically interact with an organic compound and surely prevent metal ions from proliferating into the light-emitting layer 5. As the result, this range of the ratio can preferably prevent the luminance of light emission from decreasing due to time elapse and driving of the light-emitting element 1.

The light-emitting element 1 can be manufactured by the following process, for example. First, the substrate 2 is prepared and the anode 3 is formed on the substrate 2.

The anode 3 can be formed by the following methods, for example: chemical vapor deposition (CVD) including plasma CVD, thermal CVD, and laser CVD; vacuum deposition; sputtering; dry plating such as ion plating; wet plating including electrolytic plating, immersion plating, and electroless plating; spraying; sol-gel processing; metalorganic deposition (MOD); and joining of metal foil. Next, the hole transportation layer 4 is formed on the anode 3.

The hole transportation layer 4 can be formed by supplying a material for forming the hole transportation layer to the surface of the anode 3 and then, dry it (dissociating a solvent or solution.) Such material is composed of a hole transportation material that is dissolved into solvent and dispersed into a dispersion medium.

A hole transportation material can be supplied by the following coating methods, for example; spin coating, casting, micro gravure coating, gravure coating, bar coating, wire-bar coating, dip coating, spray coating, screen printing, flexographic printing, offset printing, and inkjet printing. These coating methods relatively easily form the hole transportation layer 4.

As a solvent or dispersion media for blending a hole transportation material, the following non-organic solvents, organic solvents or mixed solvent including them are cited. Non organic solvents are nitric acid vitriolic acid, ammonia, hydrogen peroxide, water, carbon bisulfide, carbon tetrachloride, and ethylene carbonate. Organic solvents are a keton group solvent such as methyl ethyl ketone (MEK), acetone, diethyl ketone, methyl isobutyl keton(MIBK), methyl isopropyl keton (MIPK), and cyclohexane; an alcohol group solvent such as methanol, ethanol, isopropanol, ethylene glycol, diethylene glycol(DEG), glycerin; an ether group solvent such as diethyl ether, disopropyl ether, 1,2-dimethoxyethane (DME), 1,4-dioxane, tetrahydrofuran(THF), tetrahydropyran (THP), anisole, diethylene glycol dimethyl ether (diglym), and diethylene glycol ethyl ether (carbitol); a cellosolve group solvent such as methyl cellosolve, ethyl cellosolve, and phenyl cellosolve; an aliphatic carbon hydride group solvent such as hexan, pentane, heptane, and cyclohexane; an aromatic carbon hydride group solvent such as toluene, xylene and benzene; an aromatic heterocycle compound group solvent such as pyridine, pyrazine, furan, pyrrole, thiophene, and methyl pyrolidone; an amide group solvent such as N,N-dimethyl formamide(DMF), N,N-dimethyl acetamide (DMA); a halogen group solvent such as chlorobenzene, dichloromethane, chloroform, and1,2-dichloroethane; an ester group solvent such as acetic ether, acetic methyl, formic ether, a sulfuric compound group solvent such as dimethyl sulfoxide (DMSO), and sulfolane; and an organic acid group solvent such as formic acid, acetic acid, trichloro acetic acid, trifluoro acetic acid.

Here, the hole transportation material is dried under atmospheric pressure or depressurized atmosphere, thermal treatment, and adding non active gas, for example.

The surface of the anode 3 may be treated with oxygen plasma before the above process. This treatment can give lyophilic property to the surface of the anode 3, remove (clean) organic materials existed on the surface of the anode 3, and adjust the working function in area near the surface of the anode 3.

As the conditions for oxygen plasma treatment, it is preferable that the plasma power be 100 to 800 W, oxygen gas flow rate is 50 to 100 mL/min. The speed for carrying a treated member (the anode 3) is 0.5 to 10 mm/sec and the substrate temperature of the substrate 2 is 70 to 90° C. Next, the light-emitting layer 5 is formed on the hole transportation layer 4 (the side of one surface of the anode 3.)

The light-emitting layer 5 can be formed by supplying a material for forming a light-emitting layer to the surface of the hole transportation layer 4 and then, dry it (dissociating a solvent or solution.) Such material is composed of a light emission material that is dissolved into solvent and dispersed into a dispersion medium.

The methods for supplying a material for forming a light-emitting layer and drying it are the same explained in the above formation of the hole transportation layer 4.

Here, when using the light emission material described before, a solvent or dispersion medium for blending a material for light emission materials is preferably non polarized solvent. These examples are an aromatic carbon hydride group solvent such as toluene, xylene, cyclohexyl benzene, and benzene, dihydrobenzofuran, trimethyl benzene, tetramethyl benzene; a aromatic heterocycle compound group solvent such as pyridine, pyrazine, furan, pyrrole, thiophene, and methyl pyrolidone; an amide group solvent such as N,N-dimethyl formamide(DMF), N,N-dimethyl acetamide (DMA); an aliphatic carbon hydride group solvent such as hexan, pentane, heptane, and cyclohexane. These are used independently or as blended solvents. Next, the electron transportation layer 6 is formed on the light-emitting layer 5.

First, a material for an electron transportation layer (a liquid material) including the above mentioned organic compound and metal ions is prepared. In order to prepare a material, an organic compound and a metal compound including at least one kind of an alkali metal, alkaline earth metal and rare earth metal are dissolved into a solvent and a metal ion from a metal compound is dissociated.

Otherwise, a liquid of an organic compound and a liquid of metal ions may be independently prepared and then they are blended so that the ratio of B/A becomes a desired value. In this case, solvents for these solutions may not be dissociated and may be differentiated if they can be blended. This process can prepare solutions even when solubility of an organic compound is largely different from that of a metal compound regarding a single solvent and it is difficult to blend them with a desired volume ratio.

As a metal compound, a salt group, a halogen group, an alkoxide group, and a metallic complex are cited. The salt group is a non organic salt group such as carbonate, nitrate salt, and hydrosulfate; and a organic salt group such as acetate, acetyl acetate. The halogen group is like chloride salt and bromid. The alkoxide group is like methoxide and ethoxide. The metallic complex is like an acetylacetonato having a ligand, which is easily removable. Such metal compound preferably includes at least one kind of metallic salts and metallic complexes. These metal compounds are preferable since they are relatively stable in the atmosphere, easily handled and easily dissolves metal ions.

It is preferable that the solvent for preparing a material for a electron transportation layer does not easily swell the organic light-emitting layer 5 or dissolve it. This preparation can prevent a light emission material from changing this property and deteriorating and avoid extremely thinning a thickness of the light-emitting layer 5 because of dissolving. As a result, this preparation can prevent the emission efficiency of the light-emitting element 1 from decreasing.

Further, when the solvent and the solution of an organic compound with a metal compound are independently prepared, it is preferable that the solvent for the metal compound solution easily dissolve a metal compound and dissociate metal ions.

Viewing the above background, using a polar protic solvent as a solvent is preferable.

As a polar protic solvent, water; alcohol groups such as a multiple alcohol group and a unit alcohol group; a carboxylic acid group such as acetic acid, formic acid, meta acrylic acid; a amine group such as ethylene diamine, diethylamine; amid group such as formamide, N,N-dimethylformamide; and a phenolate group such as a phenolate, p-butyl phenolate; and an active methylene compound such as acetyl acetone and malonic acid diethyl are cited. Further, as a unit alcohol group, methanol, ethanol, propanol, butanol,benzyl alcohol,diethlene glycol mono methyl ether and as a multiple alcohol group, ethylene glycol and glycerin are cited. One or two kinds of these are combined for use.

In particular, a major component of a polar protic solvent is preferably at least one kind of water and alcohol. Water and alcohol is highly soluble to a metal compound. Hence, using at least one kind of water and alcohol as a major component of a polar protic solvent can surely dissociate metal ions from a metal compound and easily blend a material for forming an electronic transportation layer.

In particular, a unit alcohol of which numbers of carbons are from 1 to seven (from 1 to four more preferable), is preferable as alcohol. Such unit alcohol highly dissolves a metal compound.

For example, if cesium carbonate (Cs₂CO₃) as a metal compound is dissolved into a unit alcohol (R—OH), metal ions such as Cs ion is dissociated by the following reaction.
Cs₂CO₃+2ROH→2Cs(OR)+CO₂+H₂O Cs(OR)+H₂O→OCs^{++OH}^{-+ROH}

Here, an organic compound and a metal compound are blended in a material for an electron transportation layer, so that the numbers “A” should become the previously explained relationship with numbers “B” in the obtained electron transportation layer 6. “A” is numbers of elements obtained by subtracting the linked numbers of the elements such as double links or triple links from the total numbers of elements having the unshared electron pair in the organic compound. “B” is numbers of the metal ions.

For example, it will be explained that the compound shown in the following formula 11 is used as an organic compound, and Cs₂CO₃ is used as a metal compound so that the ratio B/A is 0.2.

In the compound shown in the formula 11, two numbers of N (elements having the unshared electron pair) are included. But, direct connection of elements having the unshared electron pair together does not exist. On the other hand, two Cs ions are dissociated from Cs₂CO₃. Hence, 0.2 mol of Cs₂CO₃ is blended with 0.1 mol of the compound 11 in order that B/A is 0.2.

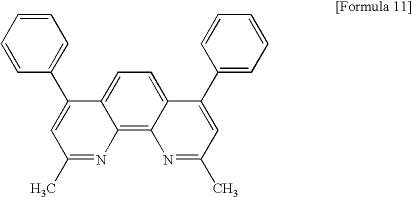

Next, a blended material for forming an electron transportation layer is supplied to the emitting layer 5 and dried (desolvation.) The electron transportation layer 6 can be formed by this process.

The methods for supplying a material for forming an electron transportation layer and drying it are the same explained in the above formation of the hole transportation layer 4, Next, the cathode 7 is formed on the electron transportation layer 6 (the opposite side to the light-emitting layer 5.)

The cathode 7 is formed by a vacuum evaporation, sputtering, applying thin metal films, coating micro particle metal inks and burning them, for example.

The emitting element 1 can be formed by the above processes.

Finally, the sealing member 8 covers over the obtained light-emitting element 1 and the element is fixed to the substrate 2.

According to the above methods, if micro particle metal inks are used, a large facility such as a vacuum evaporation is not needed so as to form an organic layer (a hole transportation layer, a light-emitting layer, an electron transportation layer), even to form a cathode, making it possible to reduce time and cost for manufacturing the light-emitting element 1. Further, applying an inkjet method (a droplet discharging method) can manufacture elements having a large area and various colored elements.

Here, in the present embodiment, the hole transportation layer 4 and the light-emitting layer 5 are formed by a liquid phase processes. But, in the invention, depending on kinds of materials for a hole transportation layer and an electron transportation layer, a gas phase processes such as a vacuum evaporation and others may be used.

The light-emitting element 1 can be used as a light source, for example. Further a plurality of light-emitting elements 1 are arranged in a matrix so that a display (a light-emitting device in the invention) can be formed.

Here, a method of driving a display is not specifically limited. Either active matrix method or a passive matrix method may be used.

Next, an example of a display using the light-emitting device of the invention is explained.

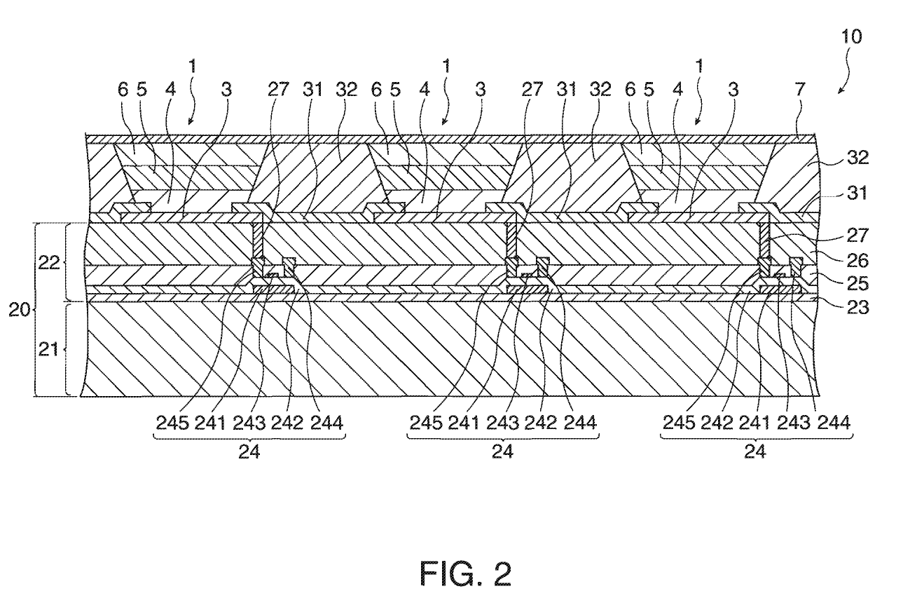

FIG. 2 shows cross section of an embodiment of a display in which the light-emitting element of the invention is applied.

A display 10 shown in FIG. 2 comprises a base 20 and a plurality of the light-emitting devices 1 formed on the base 20.

The base 20 includes a substrate 20 and a circuit portion 22 formed on the substrate 21.

The circuit portion 22 includes a protection layer 23, which is formed on the substrate 21 and made of silicon oxide for example, a TFT for driving (a switching element) 24 formed on the protection layer 23, a first interlayer protection layer 25 and a second interlayer protection layer 26.

The TFT for driving (a switching element) 24 includes a semiconductor layer 241 made of silicon, a gate insulating layer 242 formed on the semiconductor layer 241, a gate electrode layer 243 formed on the gate insulating layer 242, a source electrode 244 and a drain electrode 245.

Here, each of the light-emitting elements 1 is installed on the circuit portion 22 corresponding to the TFT for driving 24. Each of the light-emitting element 1 is partitioned from other, which is adjacent to the element 1, by a first partition wall 31 and a second partition wall 32.

In the embodiment, an anode 3 of each of the light-emitting elements 1 works as a pixel electrode and is electrically connected to a drain electrode 245 of the TFT for driving 24 via a wiring 27. Further, a cathode 7 of each of the light-emitting elements 1 is connected to a common electrode.

Further, a sealing member (not shown in the figure) covering over the light-emitting elements 1 is fixed to the base 20 so as to seal the light-emitting elements 1.

The display 1 may display monochromatic images or color images by selecting a material used for the light-emitting elements 1.

The display 10 (a display of the present invention) can be built in various types of electronic equipment.

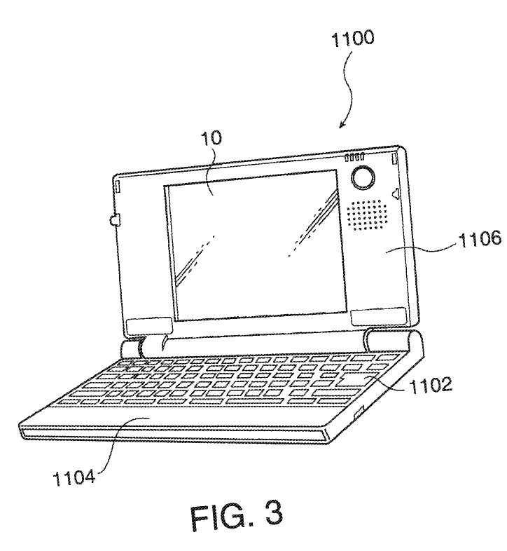

FIG. 3 is a perspective view of a mobile type (or note type) personal computer to which an electronic apparatus of the invention is applied.

In this figure, a personal computer 1100 comprises a body 1104 provided with a key board 1102, and a display unit 1106 provided with a display portion. The display unit 1106 is hold with being rotationable to the body 1104 via a hinge structure.

The personal computer 1100 is provided with a display portion in a display unit 1106 that is the display 10 of the above embodiment.

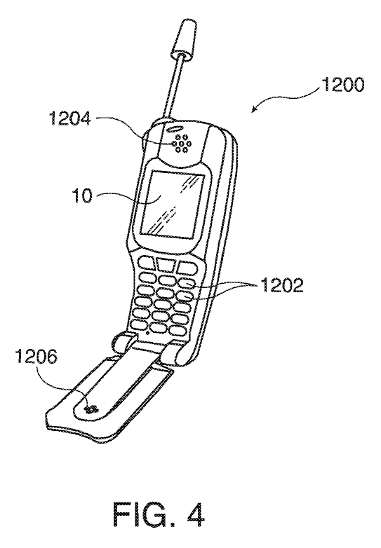

FIG. 4 is a perspective view of a mobile phone (including PHS) to which an electronic apparatus of the invention is applied.

In the figure, the mobile phone 1200 is provided with a plurality of buttons for operation 1202, a receiver 1204, a transmitter 1206 and a display portion.

The mobile phone 1200 is provided with a display portion that is the display 10 of the above embodiment.

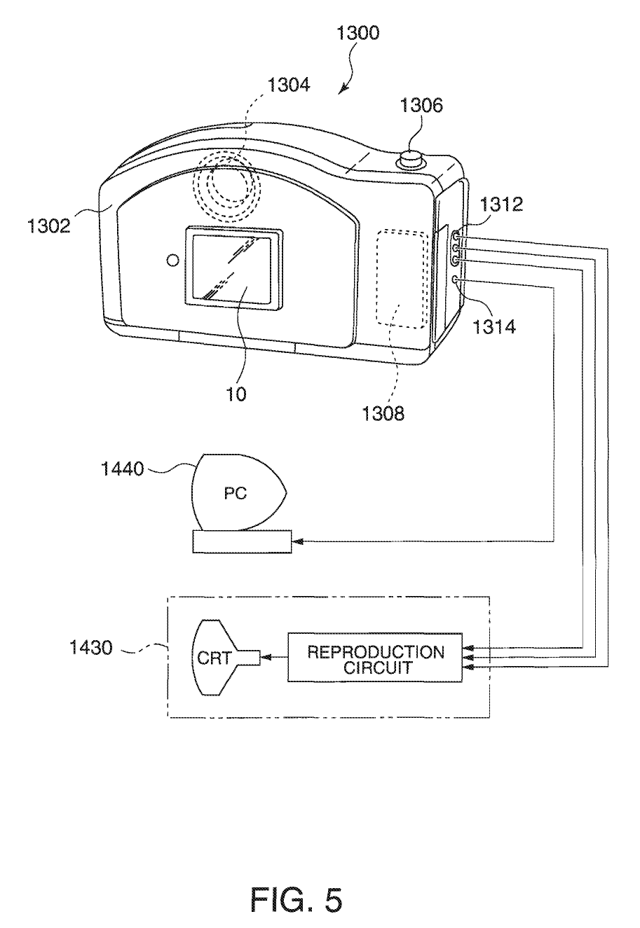

FIG. 5 is a perspective view of a digital still camera to which an electronic apparatus of the invention is applied. Here, this figure simply shows a connection to outer apparatuses.

Here, the digital still camera 1300 is provided with an image sensing device such as charged couple device (CCD) which converts an light image into electrical signals and generates an image signal, though a conventional camera uses silver halide photosensitive film that is exposed to a light image of an object.

On the back of a case (a body ) 1302 of the digital still camera 1300, a display portion is installed. This display works as a finder displaying an object as an electronic image based on an image signal from the CCD.

The digital still camera 1300 is provided with a display portion that is the display 10 of the above embodiment.

A circuit substrate 1308 is installed in the case. The circuit substrate 1308 is provided with a memory storing (memorizing) an image signal.

On the front side of the case 1302 (the back side in the figure), a light receiving unit 1304 including an optical lens (image optics) and CCD is installed.

A person, who takes a picture, confirms an object displayed in the display portion, and then presses a shutter button 1306. An image signal at that moment is sent from the CCD to the circuit substrate 1308 and stored in the circuit substrate.

Further, the digital still camera 1300 is provided with an output terminal 1312 for video signal 1312 and an input and output terminal 1314 for data communication. As shown in the figure, the output terminal 1312 for video signal is connected to a TV monitor 1430, the input and output terminal 1314 for data communication is connected to a personal computer 1440 as necessarily. Further, an image signal stored in the memory of the circuit board 1308 is output to the TV monitor 1430 and the personal computer 1440.

Here, the electronic apparatus of the invention is applied to not only the above personal computer (a mobile type personal computer) in FIG. 3, the mobile phone in FIG. 4 and the digital camera in FIG. 5, but also the following instruments. These are TVs, video cameras, viewfinder type or direct monitor type videotape recorders, laptop personal computers, automobile navigation devices, pagers, electronic notes (including communication function), electronic dictionaries, electronic calculators, electronic game devices, word processors, workstations, TV phones, TV monitors for security, electronic binoculars, Pos terminals, instruments with touch panels such as cash dispensers in finance institutions and vending machines, medical instruments such as electronic thermometers, blood-pressure gauges, blood glucose gauges, electrocardiograph displays, ultrasound diagnostic devices, and endoscopic displays, fish detectors, various measuring instruments, measuring gauges for automobiles, air planes and ships, flight simulators, other various monitors and projection type displays such as projectors.

Embodiments of the invention with respect to an organic light-emitting element, a method of manufacturing an organic light-emitting element, a light-emitting device, and an electronic apparatus were described the above. But the invention is not limited to them.

In the organic light-emitting element of the invention, one layer or more can be arbitrarily added between at least one of the above layers for example.

### EXAMPLES

Specific examples of the present invention will now be described.

Manufacturing light-emitting elements

### First example

A transparent glass substrate of which average thickness is 0.5 mm is prepared. Next, an ITO electrode (an anode) of which average thickness is 100 nm is formed by a sputtering.

Then, a substrate is dipped into acetone and 2-propanol in this order and cleaned with ultrasonic wave. A water dispersion of PEDOT/PSS (poly(3-ethylenedioxythiophene/styrenesulfonate)) was applied on the anode by spin coating, and then the substrate was dried on a hotplate at 200° C.×10 minutes under normal atmosphere. The hole transportation layer of which an average thickness is 60 nm is formed by the above process. Next, a monochloro benzen solution in which polyvinyl carbazole and facotorys (2-phenylpyridine) iridium are dissolved, is coated on the hole transportation layer by spin coating and then dried. The light-emitting layer of which an average thickness is 70 nm is formed by the above process.

The volume ratio of polyvinyl carbazole to facotoris (2-phenylpyridine)iridium is 97:3. As a metal compound, cesium carbonate (Cs₂CO₃) is dissolved into 2-propanol. On the other hand, 2,9-dimethyl-4,7-diphenyl-1,10-phenanthroline (an organic compound shown as the formula 11) is dissolved into N,N-dimethylformamide.

Then, these solutions are mixed so that the concentration of 2,9-dimethyl-4,7-diphenyl-1,10-phenanthroline is 0.5 wt %. A material for forming an electron transportation layer is formed by the above process.

Here, the mixed mol ratio of 2,9-dimethyl-4,7-diphenyl-1,10-phenanthroline to cesium carbonate was 1:0.1. Namely, the above B/A ratio was 0.1.

This arranged material for forming an electron transportation was applied to the light-emitting layer by spin coating, and then the substrate was dried on a hotplate at 130° C.×10 minutes under nitric atmosphere. The electron transportation layer of which an average thickness is 15 nm is formed by the above process. Next, an Al electrode (a cathode) of which average thickness is 200 nm is formed on a electron transportation layer by vacuum evaporation.

Next, a protection layer(a sealing member) made of glass covers over formed layers and is fixed and sealed with epoxy resin.

### Second Example

In the process of 5), the mixed mol ratio of 2,9-dimethyl-4,7-diphenyl-1,10-phenanthroline to cesium carbonate was 1:0.3, making the ratio B/A being 0.3. Other processes except this ratio was the similar to the example 1 for forming a light-emitting element.

### Third Example

In the process of 5), the mixed mol ratio of 2,9-dimethyl-4,7-diphenyl-1,10-phenanthroline to cesium carbonate was 1:0.5, making the ratio B/A being 0.5. Other processes except this ratio was the similar to the example 1 for forming a light-emitting element.

### Fourth Example

In the process of 5), the mixed mol ratio of 2,9-dimethyl-4,7-diphenyl-1,10-phenanthroline to cesium carbonate was 1:0.7, making the ratio B/A being 0.7. Other processes except this ratio was the similar to the example 1 for forming a light-emitting element.

### Fifth example

In the process of 5), as a metal compound, lithium acetylacetonate(Li(acac)) was used. The mixed mol ratio of 2,9-dimethyl-4,7-diphenyl-1,10-phenanthroline to lithium acetylacetonate was 1:1, making the ratio B/A being 0.5. Other processes except this ratio was the similar to the example 1 for forming a light-emitting element.

### Six Example

In the process of 5), as a metal compound, calcium chlorite (CaCl₂) was used. The mixed mol ratio of 2,9-dimethyl-4,7-diphenyl-1,10-phenanthroline to cesium carbonate was 1:1, making the ratio B/A being 0.5. Other processes except this ratio was the similar to the example 1 for forming a light-emitting element.

### Seven example

In the process of 5}, as a organic compound, 1,1′-thiocarbonyl diimidazole (a organic compound shown in the formula 6) was used and as a metal compound, ytterbium chloride (YbCl₃) was used. The mixed mol ratio of 1,1′-thiocarbonyl diimidazole to ytterbium chloride was 1:2.5, making the ratio B/A being 0.5. Other processes except this ratio was the similar to the example 1 for forming a light-emitting element.

### First Comparison

In the process of 5), mixing of cesium carbonate was omitted. Other processes except this omission was the similar to the example 1 for forming a light-emitting element.

### Second comparison

In the process of 5), cesium carbonate was co-evaporated with 2,9-dimethyl-4,7-diphenyl-1,10-phenanthroline to form an electron transportation layer. Other processes except this co-evaporation was the similar to the example 1 for forming a light-emitting element.

Here, the mixed mol ratio of 2,9-dimethyl-4,7-diphenyl-1,10-phenanthroline to cesium carbonate was 1:0.5.

### Third Comparison

In the process of 5), mixing of lithium acetylacetonate was omitted. Other processes except this omission was the similar to the example 5 for forming a light-emitting element.

### Fourth Comparison

In the process of 5), mixing of calcium chlorite was omitted. Other processes except this omission was the similar to the example 6 for forming a light-emitting element.

### Fifth comparison

In the process of 5), mixing of ytterbium chloride was omitted. Other processes except this omission was the similar to the example 7 for forming a light-emitting element.

### Evaluation

2-1. Confirming the Existence of Metal ions

In the above embodiments and examples, the electronic state of metals existing in an electron transformation layer was confirmed by X ray photoelectric spectroanalysis (XPS) before forming Al electrodes.

Here, the XPS device (Quantera SXM) made by PHI was used for the X ray photoelectric spectroanalysis.

As a result, the existence of metal ions was confirmed in the each of electron transformation layers in the above examples.

2-2. Evaluation of the Light Emission Efficiency

Regarding light-emitting elements manufactured in the above examples and comparisons, 8V DC voltage is applied between the anode and the cathode, measuring a current value and brightness. Then, the light emission efficiency [cd/A] was obtained from these values.

2-3. Evaluation of the Endurance

Regarding light-emitting elements manufactured in the above examples and comparisons, DC voltage is applied between the anode and the cathode, measuring a constant current drive with the initial brightness: 4 Cde/m². Then a half life time, which. is time when the brightness becomes a half from the original, was obtained. The table 1 shows the evaluation results of 2-2 evaluation of the light emission efficiency and 2-3 evaluation of the endurance.

TABLE 1

| | | | | | Evaluation result of | |
|---|---|---|---|---|---|---|
| | Electron transportation layer | | | | light emitting | Evaluation result of |
| | | | | Method of | efficiency | endurance |
| | Organic compound | Metal compound | B/A | forming a film | (relative value) | (relative value) |
| Example 1 | 2,9-dimethyl-4,7-diphenyl-1,10- | cesium | 0.1 | Liquid phase | 1.1 | 1.5 |
| | phenanthroline | carbonate | | | | |
| Example 2 | 2,9-dimethyl-4,7-diphenyl-1,10- | cesium | 0.3 | Liquid phase | 1.3 | 2.8 |
| | phenanthroline | carbonate | | | | |
| Example 3 | 2,9-dimethyl-4,7-diphenyl-1,10- | cesium | 0.5 | Liquid phase | 1.5 | 3.0 |
| | phenanthroline | carbonate | | | | |
| Example 4 | 2,9-dimethyl-4,7-diphenyl-1,10- | cesium | 0.7 | Liquid phase | 1.2 | 1.6 |
| | phenanthroline | carbonate | | | | |
| Comparison 1 | 2,9-dimethyl-4,7-diphenyl-1,10- | — | 0 | Liquid phase | 1 | 1 |
| | phenanthroline | | | | | |
| Comparison 2 | 2,9-dimethyl-4,7-diphenyl-1,10- | cesium | 0.5 | Gas phase | 1.3 | 1.4 |
| | phenanthroline | carbonate | | (Co-evaporation) | | |
| Example 5 | 2,9-dimethyl-4,7-diphenyl-1,10- | lithium | 0.5 | Liquid phase | 1.5 | 2.5 |
| | phenanthroline | acetylacetonate | | | | |
| Comparison 3 | 2,9-dimethyl-4,7-diphenyl-1,10- | — | 0 | Liquid phase | 1 | 1 |
| | phenanthroline | | | | | |
| Example 6 | 2,9-dimethyl-4,7-diphenyl-1,10- | cesium | 0.5 | Liquid phase | 1.2 | 1.5 |
| | phenanthroline | carbonate | | | | |
| Comparison 4 | 2,9-dimethyl-4,7-diphenyl-1,10- | — | 0 | Liquid phase | 1 | 1 |
| | phenanthroline | | | | | |
| Example 7 | 1,1′-thiocarbonyl diimidazole | ytterbium | 0.5 | Liquid phase | 1.3 | 2.0 |
| | | chloride | | | | |
| Comparison 5 | 1,1′-thiocarbonyl diimidazole | — | 0 | | 1 | 1 |

Here, in the table 1, examples 1 to 4 and the comparison 2 show the relative values when the value of the comparison 1 is 1. The example 5 shows the relative values when the value of the comparison 3 is 1. The example 6 shows the relative values when the value of the comparison 4 is 1. The example 7 shows the relative values when the value of the comparison 5 is 1.

As shown in the table 1, light-emitting elements manufactured in the above examples attained the excellent light emission efficiency and endurance.

On the other hand, light-emitting elements manufactured in the above comparisons showed inferiority in the light emission efficiency and endurance.

Here, there was a tendency of increasing the light emission efficiency and endurance in the comparison 2 in which a metal compound was mixed in an electron transportation layer and in the comparison 1 in which a metal compound was mixed in an electron transportation layer. However, this level was far from reaching the level of the examples in which metal ions were mixed in an electron transportation layer.

What is claimed is:

1. An organic light-emitting element comprising:
an anode;
an organic light-emitting layer formed on one surface of the anode;
an electron transportation layer formed on the organic light-emitting layer, the electron transportation layer including an organic compound with electron transportation characteristic having at least one element that holds a unshared electron pair, and the electron transportation layer including a metal ion that is at least one kind of an alkali metal ion, alkaline earth metal ion and rare earth metal ion; and
a cathode formed on a side being opposite to the organic light-emitting layer with respect to the electron transportation layer.

2. The organic light-emitting element according to claim 1, wherein the element holding an unshared electron pair is at least one kind of N, O, P, S, As and Se.

3. The organic light-emitting element according to claim 1, wherein the organic compound is a condensed heterocycle compound including the element with the unshared electron pair or its derivative.

4. The organic light-emitting element according to claim 1, wherein the element with the unshared electron pair included in the organic compound is linked with other element such as double or triple links and polarized to the other linked element.

5. The organic light-emitting element according to claim 1, wherein the weight ratio of the metal ion to the organic compound during transposing electrons is expressed as the following: B/A is equal to or more than 0.2, where A is numbers of elements that are obtained by subtracting the linked numbers of the elements such as double links or triple links from the total numbers of elements having the unshared electron pair in the organic compound and B is numbers of the metal ions.

6. A method of manufacturing the light-emitting element according to claim 1, comprising:
compounding a liquid material including the organic compound and the metal ion by dissolving the organic compound and a metal compound including one kind of an alkali metal, alkaline earth metal and rare earth metal into a solvent and dissociating a metal ion from the metal compound;
forming the electron transportation layer by supplying the liquid material onto the organic light-emitting layer and drying the liquid material; and
forming the cathode on the side opposite to the organic light-emitting layer with respect to the electron transportation layer.

7. The method of manufacturing the organic light-emitting element according to claim 6, wherein the compounding a liquid material mixes a first solution in which the organic compound is dissolved with a second solution in which the metal compound is dissolved so that the weight ratio of the metal ion to the organic compound during transposing electrons is expressed as the following: B/A is equal to or more than 0.2, where A is numbers of elements that are obtained by subtracting the linked numbers of the elements such as double links or triple links from the total numbers of elements having the unshared electron pair in the organic compound and B is numbers of the metal ions.

8. The method of manufacturing the organic light-emitting element according to claim 6, wherein the solvent does not easily expand the organic light-emitting layer or dissolve the organic light-emitting layer.

9. The method of manufacturing the organic light-emitting element according to claim 6, wherein the solvent is a polar protic solvent.

10. The method of manufacturing the organic light-emitting element according to claim 9, wherein a major component of the polar protic solvent is at least one kind of water and alcohol.

11. The method of manufacturing the organic light-emitting element according to claim 10, wherein the alcohol is a unit alcohol in which the numbers of carbons are one to seven.

12. The method of manufacturing the organic light-emitting element according to claim 6, wherein the metal compound is at least one kind of a metal salt and a metal complex.

13. An electronic circuit comprising the organic light-emitting element according to claim 1.

14. An electronic instrument comprising the organic light-emitting element according to claim 13.
